(19) United States
(12) Patent Application Publication
(10) Pub. No.: US 2026/0283014 A1
(43) Pub. Date: Sep. 17, 2026

(54) SEMICONDUCTOR STRUCTURE AND MANUFACTURING METHOD THEREOF

(71) Applicant: Powerchip Semiconductor Manufacturing Corporation, Hsinchu (TW)

(72) Inventors: Shou-Zen Chang, Hsinchu City (TW); Chun-Lin Lu, Hsinchu City (TW); Cheng-Hung Chang, Hsinchu (TW); Pei-Rong Ni, Hsinchu (TW)

(73) Assignee: Powerchip Semiconductor Manufacturing Corporation, Hsinchu (TW)

(21) Appl. No.: 19/091,864

(22) Filed: Mar. 27, 2025

(30) Foreign Application Priority Data
Mar. 12, 2025 (TW) 114109226

(51) Int. Cl. H10W 90/00; H10W 72/00; H10W 72/30; H10W 90/20; H10W 90/26

(52) U.S. Cl. CPC H10W 90/00; H10W 72/073; H10W 72/07307; H10W 72/07331; H10W 72/322; H10W 90/26; H10W 90/297; H10W 90/732

(57) ABSTRACT

A semiconductor structure including a carrier wafer structure and transistor wafer structures is provided. The transistor wafer structures are stacked on the carrier wafer structure. Each of the transistor wafer structures includes a transistor wafer, a first bonding layer, and a second bonding layer. The transistor wafer has a first side and a second side opposite to each other. The first bonding layer is located on the first side of the transistor wafer. The second bonding layer is located on the second side of the transistor wafer. The first bonding layer of one of two adjacent transistor wafer structures is bonded to the second bonding layer of the other of the two adjacent transistor wafer structures.

### CROSS-REFERENCE TO RELATED APPLICATION

This application claims the priority benefit of Taiwan application serial no. 114109226, filed on Mar. 12, 2025. The entirety of the above-mentioned patent application is hereby incorporated by reference herein and made a part of this specification.

### BACKGROUND

### Technical Field

The invention relates to a semiconductor structure and a manufacturing method thereof, and particularly relates to a semiconductor structure including a transistor and a manufacturing method thereof.

### Description of the Related Art

In the current semiconductor manufacturing process, a semiconductor structure using an epitaxial process to stack transistors has been developed. However, how to minimize the thickness of the transistor wafer and reduce the process complexity of the semiconductor structure are the goals of continuous efforts.

### SUMMARY

The invention provides a semiconductor structure and a manufacturing method thereof, which can minimize the thickness of the transistor wafer and reduce the process complexity of the semiconductor structure.

The invention provides a semiconductor structure, which includes a carrier wafer structure and transistor wafer structures. The transistor wafer structures are stacked on the carrier wafer structure. Each of the transistor wafer structures includes a transistor wafer, a first bonding layer, and a second bonding layer. The transistor wafer has a first side and a second side opposite to each other. The first bonding layer is located on the first side of the transistor wafer. The second bonding layer is located on the second side of the transistor wafer. The first bonding layer of one of two adjacent transistor wafer structures is bonded to the second bonding layer of the other of the two adjacent transistor wafer structures.

According to an embodiment of the invention, in the semiconductor structure, the transistor wafer may include a transistor.

According to an embodiment of the invention, in the semiconductor structure, the transistor is, for example, a planar field-effect-transistor (FET), a fin field-effect-transistor (Fin FET), a gate-all-around field-effect-transistor (GAA FET), or a complementary field-effect-transistor (CFET).

According to an embodiment of the invention, in the semiconductor structure, the transistor is, for example, an N-type metal oxide semiconductor (NMOS) transistor, a P-type metal oxide semiconductor (PMOS) transistor, or a combination thereof.

According to an embodiment of the invention, in the semiconductor structure, the carrier wafer structure may include a carrier wafer and a third bonding layer. The third bonding layer is located on the carrier wafer.

According to an embodiment of the invention, in the semiconductor structure, the first bonding layer closest to the carrier wafer structure may be bonded to the third bonding layer.

According to an embodiment of the invention, the semiconductor structure may further include a first dielectric layer and a routing structure. The first dielectric layer is located on the transistor wafer structure farthest from the carrier wafer structure. The routing structure is located in the first dielectric layer.

According to an embodiment of the invention, the semiconductor structure may further include a via. The via passes through the transistor wafer structures. The via may be electrically connected to the routing structure and the transistor wafer structures.

According to an embodiment of the invention, the semiconductor structure may further include vias. The vias are located in the transistor wafer structures and are connected to each other. The vias may be electrically connected to the routing structure and the transistor wafer structures.

According to an embodiment of the invention, the semiconductor structure may further include a first dielectric layer and a routing structure. The first dielectric layer is located on the transistor wafer structure closest to the carrier wafer structure. The routing structure is located in the first dielectric layer.

According to an embodiment of the invention, in the semiconductor structure, the first dielectric layer may be bonded to the third bonding layer.

According to an embodiment of the invention, the semiconductor structure may further include a second dielectric layer and an interconnect structure. The second dielectric layer is located on the transistor wafer structure farthest from the carrier wafer structure. The interconnect structure is located in the second dielectric layer.

According to an embodiment of the invention, the semiconductor structure may further include a via. The via passes through the transistor wafer structures. The via may be electrically connected to the routing structure, the transistor wafer structures, and the interconnect structure.

According to an embodiment of the invention, the semiconductor structure may further include vias. The vias are located in the transistor wafer structures and are connected to each other. The vias may be electrically connected to the routing structure, the transistor wafer structures, and the interconnect structure.

According to an embodiment of the invention, in the semiconductor structure, the thickness of the transistor wafer may be less than 300 nanometers (nm).

The invention provides a manufacturing method of a semiconductor structure, which includes the following steps. A carrier wafer structure is provided. Transistor wafer structures are formed on the carrier wafer structure. Each of the transistor wafer structures includes a transistor wafer, a first bonding layer, and a second bonding layer. The transistor wafer has a first side and a second side opposite to each other. The first bonding layer is located on the first side of the transistor wafer. The second bonding layer is located on the second side of the transistor wafer. The first bonding layer of one of two adjacent transistor wafer structures is bonded to the second bonding layer of the other of the two adjacent transistor wafer structures.

According to an embodiment of the invention, in the manufacturing method of the semiconductor structure, the carrier wafer structure may include a first carrier wafer and a third bonding layer. The third bonding layer is located on the first carrier wafer. The first bonding layer closest to the first carrier wafer may be bonded to the third bonding layer.

According to an embodiment of the invention, in the manufacturing method of the semiconductor structure, the method of forming each of the transistor wafer structures may include the following steps. A second carrier wafer is provided. A release layer is formed on the second carrier wafer. The second bonding layer is formed on the release layer. The transistor wafer is formed on the second bonding layer. The first bonding layer is formed on the transistor wafer.

According to an embodiment of the invention, in the manufacturing method of the semiconductor structure, the method of forming the transistor wafer on the second bonding layer may include bonding the transistor wafer to the second bonding layer.

According to an embodiment of the invention, the manufacturing method of the semiconductor structure may further include the following steps. After bonding the first bonding layer closest to the carrier wafer structure to the third bonding layer or bonding the first bonding layer of one of the two adjacent transistor wafer structures to the second bonding layer of the other of the two adjacent transistor wafer structures, the second carrier wafer is removed from the release layer. After removing the second carrier wafer, the release layer is removed.

Based on the above description, in a semiconductor structure and a manufacturing method thereof according to the invention, the semiconductor structure includes a carrier wafer structure and transistor wafer structures. The transistor wafer structures are stacked on the carrier wafer structure. Each of the transistor wafer structures includes a transistor wafer, a first bonding layer, and a second bonding layer. The transistor wafer has a first side and a second side opposite to each other. The first bonding layer is located on the first side of the transistor wafer. The second bonding layer is located on the second side of the transistor wafer. The first bonding layer of one of two adjacent transistor wafer structures is bonded to the second bonding layer of the other of the two adjacent transistor wafer structures. In this way, each transistor wafer can be manufactured independently, thereby minimizing the thickness of the transistor wafer and reducing the process complexity of the semiconductor structure.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A-1H are cross-sectional views of a manufacturing process of a semiconductor structure according to some embodiments of the invention.

FIG. 2 is a cross-sectional view of a semiconductor structure according to other embodiments of the invention.

FIG. 3 is a cross-sectional view of a semiconductor structure according to other embodiments of the invention.

FIG. 4 is a cross-sectional view of a semiconductor structure according to other embodiments of the invention.

FIG. 5 is a cross-sectional view of a semiconductor structure according to other embodiments of the invention.

FIG. 6 is a cross-sectional view of a semiconductor structure according to other embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. In fact, the dimensions of the various features may be arbitrarily increased or reduced for clarity of discussion.

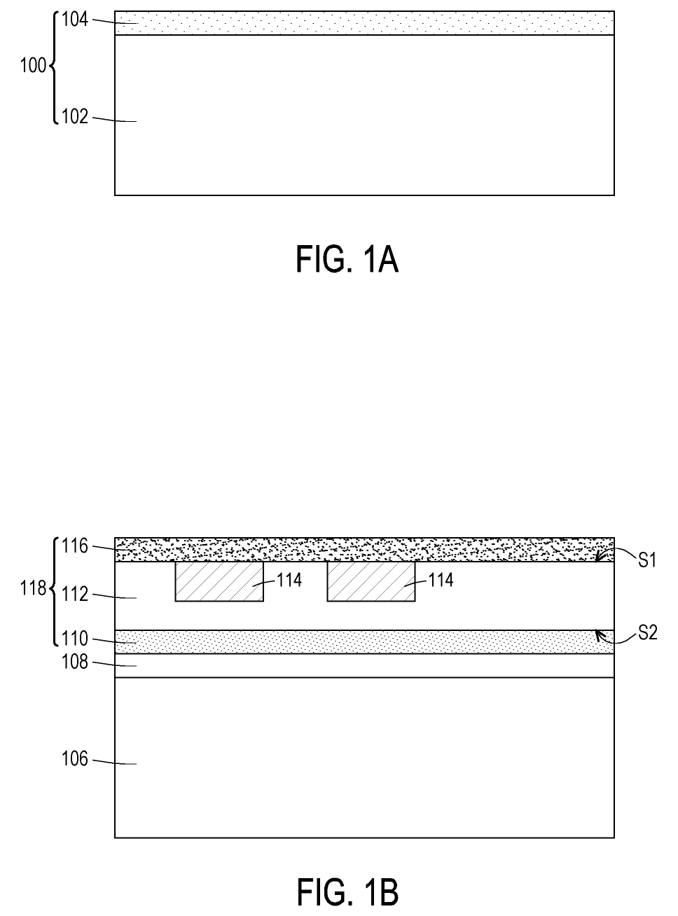

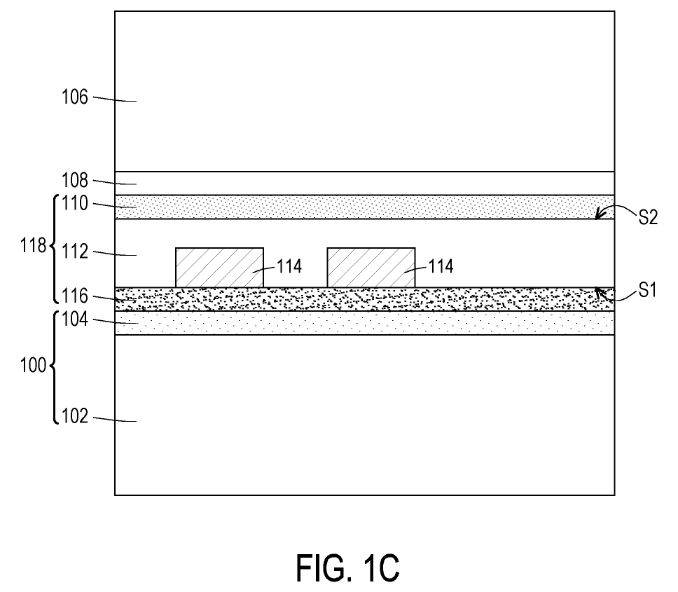

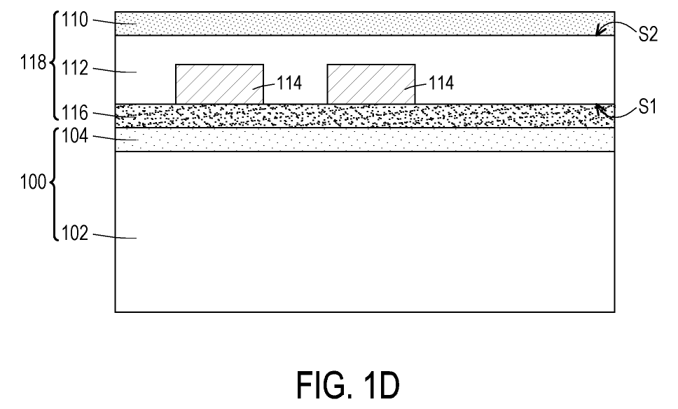

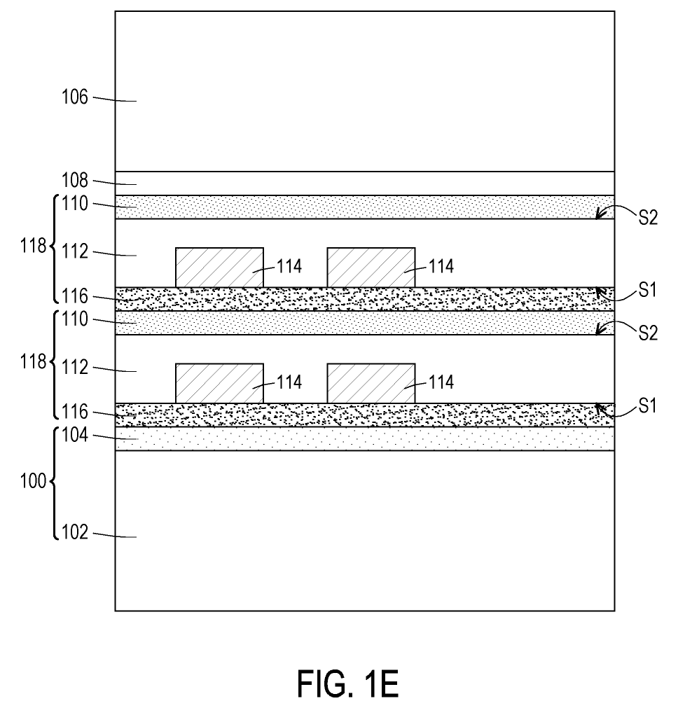

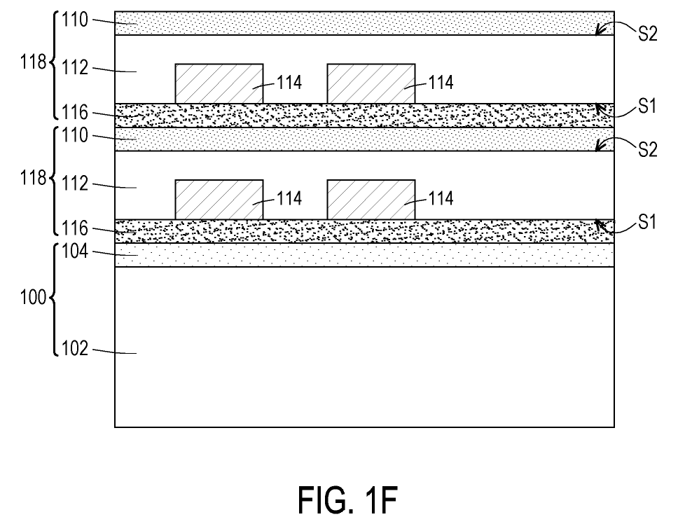

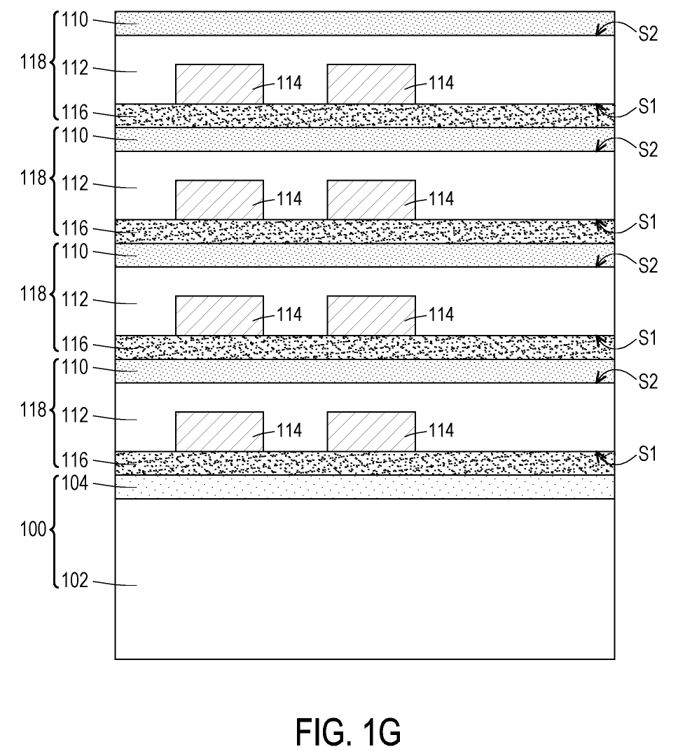

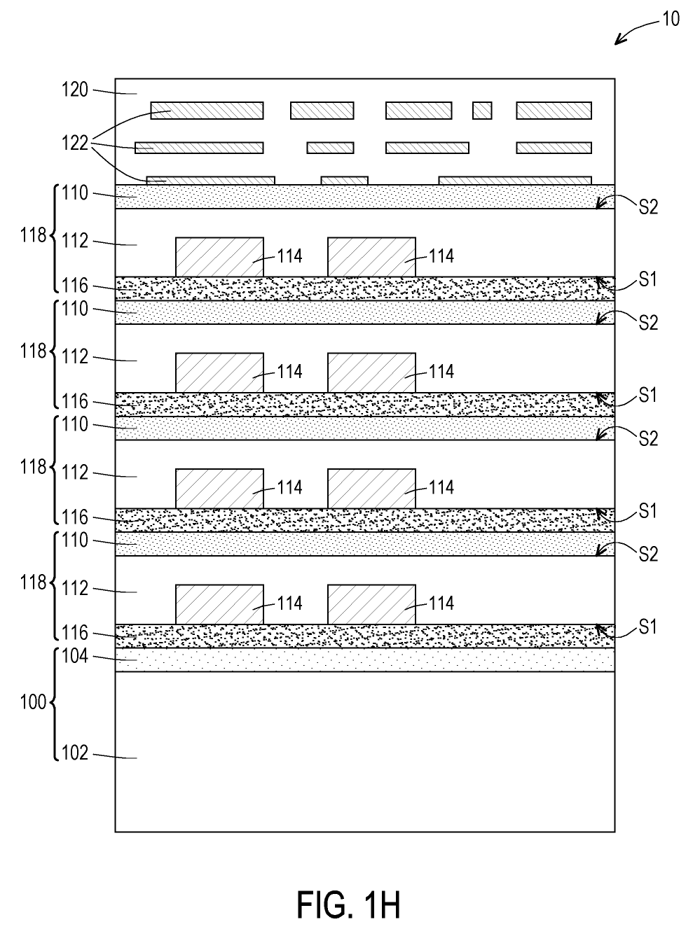

FIGS. 1A-1H are cross-sectional views of a manufacturing process of a semiconductor structure according to some embodiments of the invention.

Referring to FIG. 1A, a carrier wafer structure 100 is provided. The carrier wafer structure 100 may include a carrier wafer 102 and a bonding layer 104. In some embodiments, the carrier wafer 102 may be a semiconductor wafer such as a silicon wafer, but the invention is not limited thereto. The bonding layer 104 is located on the carrier wafer 102. In some embodiments, the material of the bonding layer 104 is, for example, silicon oxide.

Referring to FIG. 1B, a carrier wafer 106 may be provided. In some embodiments, the carrier wafer 106 may be a semiconductor wafer such as a silicon wafer, but the invention is not limited thereto. A release layer 108 may be formed on the carrier wafer 106. In some embodiments, the material of the release layer 108 is, for example, a mixed material of a metal material and a dielectric material. A bonding layer 110 may be formed on the release layer 108. In some embodiments, the material of the bonding layer 110 is, for example, silicon oxide.

A transistor wafer 112 may be formed on the bonding layer 110. The transistor wafer 112 may have a first side S1 and a second side S2 opposite to each other. In some embodiments, the transistor wafer 112 may include a transistor 114. In some embodiments, the transistor 114 is, for example, a planar FET, a Fin FET, a GAA FET, or a CFET. In some embodiments, the transistor 114 is, for example, an NMOS transistor, a PMOS transistor, or a combination thereof. In some embodiments, the thickness of the transistor wafer 112 may be less than 300 nm. In some embodiments, the material of the transistor wafer 112 may include silicon, silicon germanium (SiGe), superlattice material, or a combination thereof. In some embodiments, the method of forming the transistor wafer 112 on the bonding layer 110 may include bonding the transistor wafer 112 to the bonding layer 110. In addition, although not shown in the figure, the transistor wafer 112 may further include required components such as a dielectric layer and/or an interconnect structure.

A bonding layer 116 may be formed on the transistor wafer 112. In some embodiments, the material of the bonding layer 116 is, for example, silicon oxide. By the above method, a transistor wafer structure 118 may be formed. The transistor wafer structure 118 may include the transistor wafer 112, the bonding layer 116, and the bonding layer 110. The bonding layer 116 is located on the first side S1 of the transistor wafer 112. The bonding layer 110 is located on the second side S2 of the transistor wafer 112.

Referring to FIG. 1C, the bonding layer 116 may be bonded to the bonding layer 104. In some embodiments, the method of bonding the bonding layer 116 to the bonding layer 104 is, for example, a fusion bonding method or a hybrid bonding method.

Referring to FIG. 1D, after bonding the bonding layer 116 to the bonding layer 104, the carrier wafer 106 may be removed from the release layer 108. In some embodiments, the method of removing the carrier wafer 106 from the release layer 108 is, for example, a laser removal method.

After removing the carrier wafer 106, the release layer 108 may be removed. In some embodiments, the method of removing the release layer 108 is, for example, a dry etching method or a wet etching method.

Referring to FIG. 1E, the structure as shown in FIG. 1B may be provided. In addition, the details of the structure of FIG. 1B may refer to the description of FIG. 1B, and the description thereof is not repeated here. The bonding layer 116 of one of two adjacent transistor wafer structures 118 may be bonded to the bonding layer 110 of the other of the two adjacent transistor wafer structures 118. In some embodiments, the method of bonding the bonding layer 116 of one of the two adjacent transistor wafer structures 118 to the bonding layer 110 of the other of the two adjacent transistor wafer structures 118 is, for example, a fusion bonding method or a hybrid bonding method.

Referring to FIG. 1F, after bonding the bonding layer 116 of one of the two adjacent transistor wafer structures 118 to the bonding layer 110 of the other of the two adjacent transistor wafer structures 118, the carrier wafer 106 may be removed from the release layer 108. In some embodiments, the method of removing the carrier wafer 106 from the release layer 108 is, for example, a laser removal method.

After removing the carrier wafer 106, the release layer 108 may be removed. In some embodiments, the method of removing the release layer 108 is, for example, a dry etching method or a wet etching method.

Referring to FIG. 1G, the steps of FIGS. 1E and 1F may be repeated to obtain a structure shown in FIG. 1G. By using the above method, the transistor wafer structures 118 may be formed on the carrier wafer structure 100. Each of the transistor wafer structures 118 includes a transistor wafer 112, a bonding layer 116, and a bonding layer 110. Furthermore, the transistor wafers 112 of the transistor wafer structures 118 may have the same or different transistor layout designs. In addition, the number of the transistor wafer structures 118 is not limited to the number shown in the figure. As long as the number of the transistor wafer structures 118 is plural, it falls within the scope of the invention.

Referring to FIG. 1H, a dielectric layer 120 and a routing structure 122 may be formed on the transistor wafer structure 118 farthest from the carrier wafer structure 100. The dielectric layer 120 may be a single-layer structure or a multilayer structure, and the number of the dielectric layers 120 is not limited to the number shown in the figure. In some embodiments, the material of the dielectric layer 120 is, for example, silicon oxide. The routing structure 122 is located in the dielectric layer 120. The routing structure 122 may be a single-layer structure or a multilayer structure, and the number of the routing structures 122 is not limited to the number shown in the figure. In some embodiments, the material of the routing structure 122 may be copper, aluminum, tungsten, or a combination thereof.

Hereinafter, the semiconductor structure 10 of above embodiments will be described with reference to FIG. 1H. In addition, although the forming method of the semiconductor structure 10 is described by taking the above-mentioned method as an example, the invention is not limited thereto.

Referring to FIG. 1H, a semiconductor structure 10 includes a carrier wafer structure 100 and transistor wafer structures 118. In some embodiments, the semiconductor structure 10 may be fabricated by using a wafer-on-wafer (WoW) process. The carrier wafer structure 100 may include a carrier wafer 102 and a bonding layer 104. The bonding layer 104 is located on the carrier wafer 102. The transistor wafer structures 118 are stacked on the carrier wafer structure 100. Each of the transistor wafer structures 118 includes a transistor wafer 112, a bonding layer 116, and a bonding layer 110. The transistor wafer 112 has a first side S1 and a second side S2 opposite to each other. In some embodiments, the first side S1 may be the front side of the transistor wafer 112, and the second side S2 may be the back side of the transistor wafer 112. The bonding layer 116 is located on the first side S1 of the transistor wafer 112. The bonding layer 110 is located on the second side S2 of the transistor wafer 112. The bonding layer 116 of one of two adjacent transistor wafer structures 118 is bonded to the bonding layer 110 of the other of the two adjacent transistor wafer structures 118. In some embodiments, the bonding layer 116 of one of the two adjacent transistor wafer structures 118 may be fusion-bonded or hybrid-bonded to the bonding layer 110 of the other of the two adjacent transistor wafer structures 118. The bonding layer 116 closest to the carrier wafer structure 100 may be bonded to the bonding layer 104. In some embodiments, the bonding layer 116 closest to the carrier wafer structure 100 may be fusion bonded or hybrid bonded to the bonding layer 104.

In some embodiments, the semiconductor structure 10 may further include a dielectric layer 120 and a routing structure 122. The dielectric layer 120 is located on the transistor wafer structure 118 farthest from the carrier wafer structure 100. The routing structure 122 is located in the dielectric layer 120. In addition, the routing structure 122 and the transistor wafer structures 118 may be electrically connected to each other. In some embodiments, the routing structure 122 and the transistor wafer structures 118 may be electrically connected to each other by conductive components (e.g., via and/or interconnect structure) (not shown).

Based on the above embodiments, in the semiconductor structure 10 and the manufacturing method thereof, the semiconductor structure 10 includes the carrier wafer structure 100 and the transistor wafer structures 118. The transistor wafer structures 118 are stacked on the carrier wafer structure 100. Each of the transistor wafer structures 118 includes the transistor wafer 112, the bonding layer 116, and the bonding layer 110. The transistor wafer 112 has the first side S1 and the second side S2 opposite to each other. The bonding layer 116 is located on the first side S1 of the transistor wafer 112. The bonding layer 110 is located on the second side S2 of the transistor wafer 112. The bonding layer 116 of one of the two adjacent transistor wafer structures 118 is bonded to the bonding layer 110 of the other of the two adjacent transistor wafer structures 118. In this way, each transistor wafer 112 can be manufactured independently, thereby minimizing the thickness of the transistor wafer 112 and reducing the process complexity of the semiconductor structure 10.

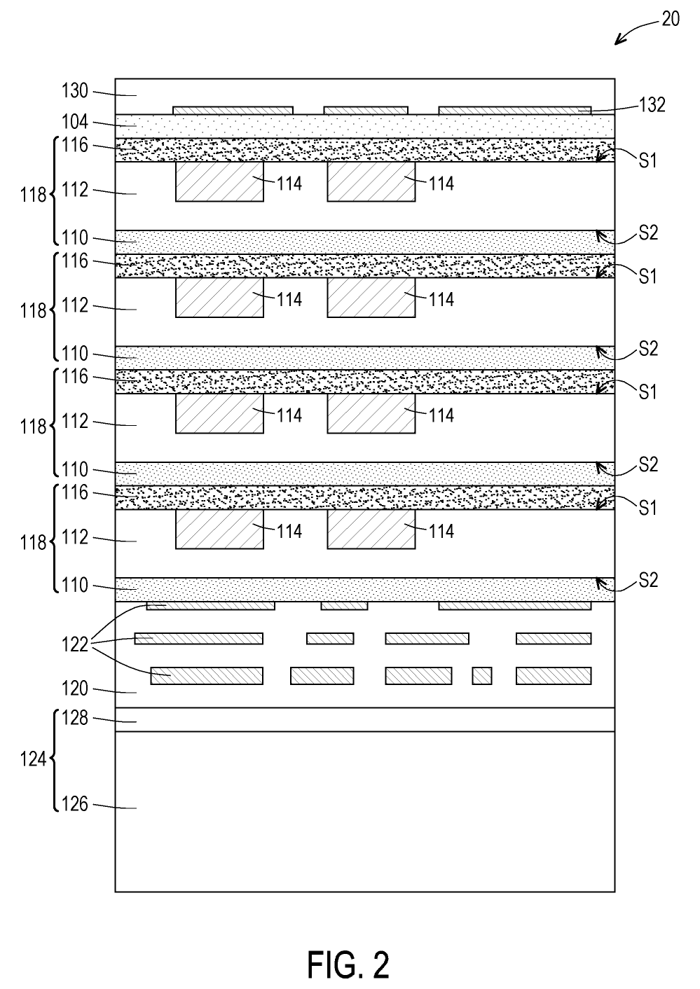

FIG. 2 is a cross-sectional view of a semiconductor structure according to other embodiments of the invention.

Referring to FIGS. 1H and 2, the difference between the manufacturing method of the semiconductor structure 20 of FIG. 2 and the manufacturing method of the semiconductor structure 10 of FIG. 1H is as follows. The manufacturing method of the semiconductor structure 20 may further include the following steps. First, a carrier wafer structure 124 may be provided. The carrier wafer structure 124 may include a carrier wafer 126 and a bonding layer 128. In some embodiments, the carrier wafer 126 may be a semiconductor wafer such as a silicon wafer, but the invention is not limited thereto. The bonding layer 128 is located on the carrier wafer 126. In some embodiments, the material of the bonding layer 128 is, for example, silicon oxide. The dielectric layer 120 may be bonded to the bonding layer 128.

The carrier wafer 102 may be removed. A dielectric layer 130 and an interconnect structure 132 may be formed on the transistor wafer structure 118 farthest from the carrier wafer structure 124. In some embodiments, the dielectric layer 130 may be located on the bonding layer 104. The dielectric layer 130 may be a single-layer structure or a multilayer structure, and the number of the dielectric layers 130 is not limited to the number shown in the figure. In some embodiments, the material of the dielectric layer 130 is, for example, silicon oxide. The interconnect structure 132 is located in the dielectric layer 130. The interconnect structure 132 may be a single-layer structure or a multilayer structure, and the number of the interconnect structures 132 is not limited to the number shown in the figure. In some embodiments, the material of the interconnect structure 132 is, for example, copper, aluminum, tungsten, or a combination thereof.

In addition, the difference between the semiconductor structure 20 of FIG. 2 and the semiconductor structure 10 of FIG. 1H is as follows. In the semiconductor structure 20, the transistor wafer structures 118 are stacked on the carrier wafer structure 124. In the semiconductor structure 20, the dielectric layer 120 may be located on the transistor wafer structure 118 closest to the carrier wafer structure 124, and the dielectric layer 120 may be bonded to the bonding layer 128.

The semiconductor structure 20 may further include a dielectric layer 130 and an interconnect structure 132. The dielectric layer 130 is located on the transistor wafer structure 118 farthest from the carrier wafer structure 124. The interconnect structure 132 is located in the dielectric layer 130. In some embodiments, the routing structure 122, the transistor wafer structures 118, and the interconnect structure 132 may be electrically connected to each other by conductive components (e.g., via and/or interconnect structure) (not shown).

In addition, in the semiconductor structure 10 of FIG. 1H and the semiconductor structure 20 of FIG. 2, the same or similar components are denoted by the same reference symbols, and the description thereof is omitted.

Based on the above embodiments, in the semiconductor structure 20 and the manufacturing method thereof, the semiconductor structure 20 includes the carrier wafer structure 124 and the transistor wafer structures 118. The transistor wafer structures 118 are stacked on the carrier wafer structure 124. Each of the transistor wafer structures 118 includes the transistor wafer 112, the bonding layer 116, and the bonding layer 110. The transistor wafer 112 has the first side S1 and the second side S2 opposite to each other. The bonding layer 116 is located on the first side S1 of the transistor wafer 112. The bonding layer 110 is located on the second side S2 of the transistor wafer 112. The bonding layer 116 of one of the two adjacent transistor wafer structures 118 is bonded to the bonding layer 110 of the other of the two adjacent transistor wafer structures 118. In this way, each transistor wafer 112 can be manufactured independently, thereby minimizing the thickness of the transistor wafer 112 and reducing the process complexity of the semiconductor structure 20.

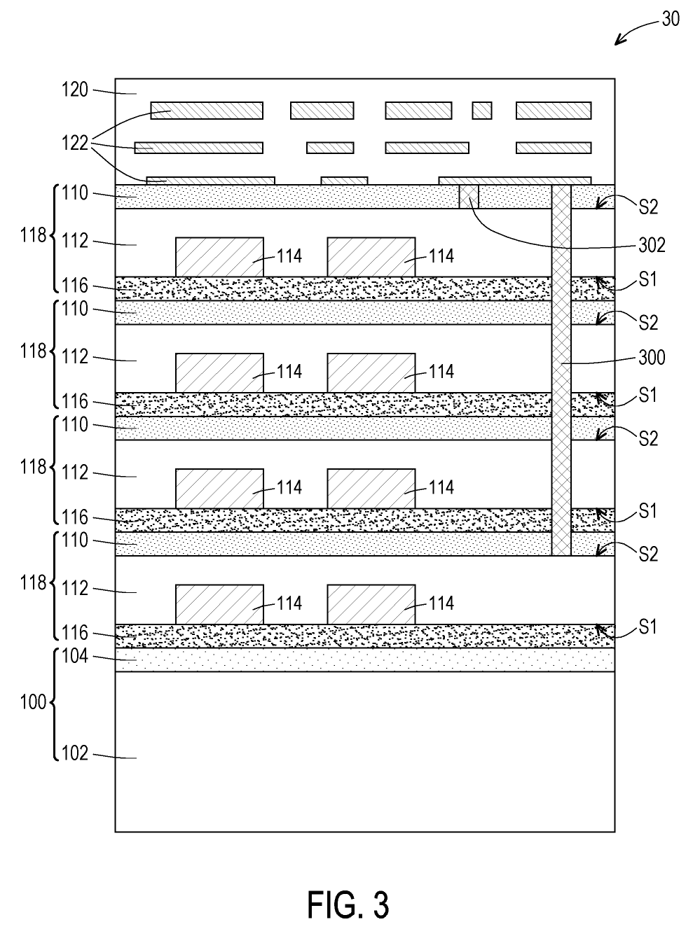

FIG. 3 is a cross-sectional view of a semiconductor structure according to other embodiments of the invention.

Referring to FIGS. 1H and 3, the difference between the semiconductor structure 30 of FIG. 3 and the semiconductor structure 10 of FIG. 1H is as follows. In the semiconductor structure 30, the electrical connection between the routing structure 122 and the transistor wafer structures 118 is illustrated as an example. The semiconductor structure 30 may further include a via 300. The via 300 passes through the transistor wafer structures 118. The via 300 may be connected to the transistor wafer 112 closest to the carrier wafer structure 100. The via 300 may be electrically connected to the routing structure 122 and the transistor wafer structures 118. Therefore, the routing structure 122 and the transistor wafer structures 118 may be electrically connected to each other by the via 300. In some embodiments, the material of the via 300 is, for example, copper or tungsten.

In some embodiments, the semiconductor structure 30 may further include a via 302. The via 302 is located between the routing structure 122 and the transistor wafer 112 closest to the routing structure 122. The via 302 may be electrically connected to the routing structure 122 and the transistor wafer 112 closest to the routing structure 122. The via 302 may be located in the bonding layer 110. In some embodiments, the material of the via 302 is, for example, copper or tungsten.

In addition, in the semiconductor structure 10 of FIG. 1H and the semiconductor structure 30 of FIG. 3, the same or similar components are denoted by the same reference symbols, and the description thereof is omitted.

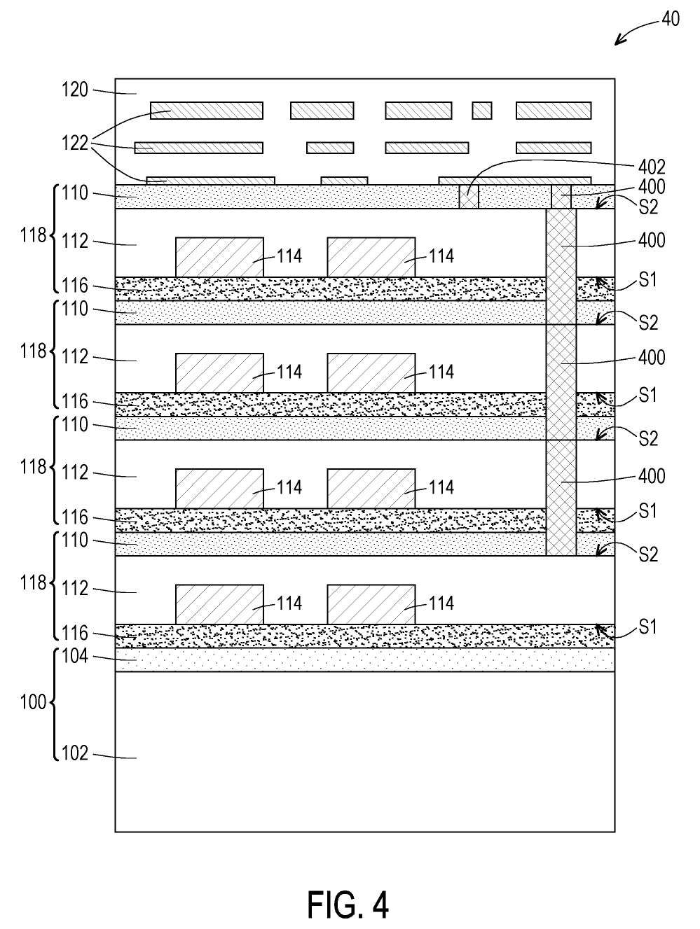

FIG. 4 is a cross-sectional view of a semiconductor structure according to other embodiments of the invention.

Referring to FIGS. 1H and 4, the difference between the semiconductor structure 40 of FIG. 4 and the semiconductor structure 10 of FIG. 1H is as follows. In the semiconductor structure 40, the electrical connection between the routing structure 122 and the transistor wafer structures 118 is illustrated as an example. The semiconductor structure 40 may further include vias 400. The vias 400 are located in the transistor wafer structures 118 and are connected to each other. The via 400 farthest from the routing structure 122 may be connected to the transistor wafer 112 closest to the carrier wafer structure 100. The vias 400 may be electrically connected to the routing structure 122 and the transistor wafer structures 118. Therefore, the routing structure 122 and the transistor wafer structures 118 may be electrically connected to each other by the vias 400. The via 400 may be a single-layer structure or a multilayer structure. In some embodiments, the material of the via 400 is, for example, copper or tungsten.

In some embodiments, the semiconductor structure 400 may further include a via 402. The via 402 is located between the routing structure 122 and the transistor wafer 112 closest to the routing structure 122. The via 402 may be electrically connected to the routing structure 122 and the transistor wafer 112 closest to the routing structure 122. The via 402 may be located in the bonding layer 110. In some embodiments, the material of the via 402 is, for example, copper or tungsten.

In addition, in the semiconductor structure 10 of FIG. 1H and the semiconductor structure 40 of FIG. 4, the same or similar components are denoted by the same reference symbols, and the description thereof is omitted.

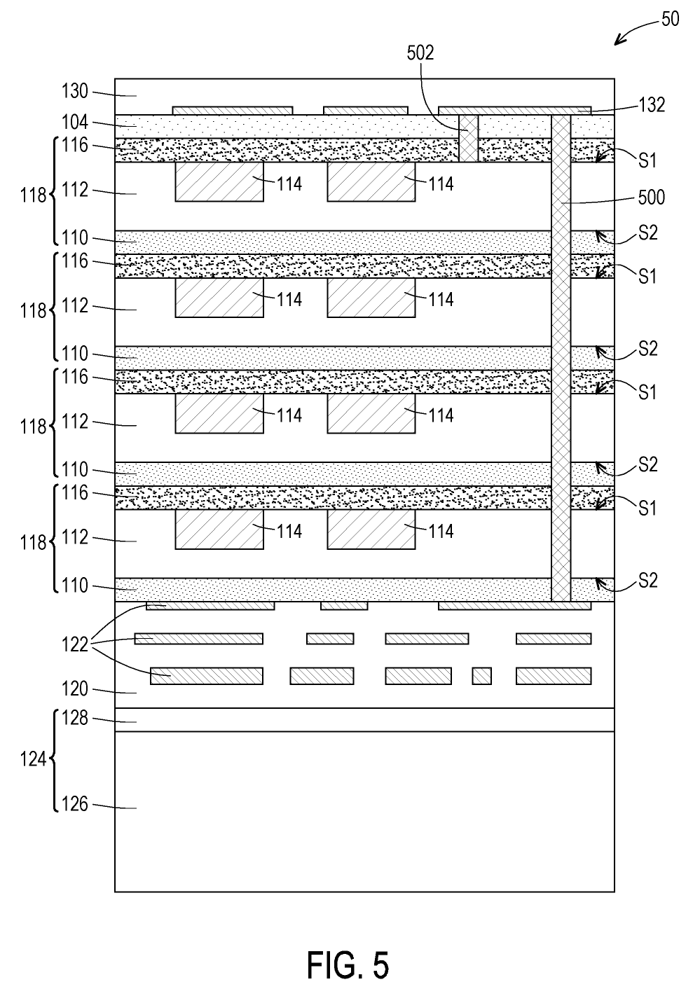

FIG. 5 is a cross-sectional view of a semiconductor structure according to other embodiments of the invention.

Referring to FIGS. 2 and 5, the difference between the semiconductor structure 50 of FIG. 5 and the semiconductor structure 20 of FIG. 2 is as follows. In the semiconductor structure 50, the electrical connection method of the routing structure 122, the transistor wafer structures 118, and the interconnect structure 132 is illustrated as an example. The semiconductor structure 50 may further include a via 500. The via 500 passes through the transistor wafer structures 118. The via 500 may further pass through the bonding layer 104. The via 500 may be electrically connected to the routing structure 122, the transistor wafer structures 118, and the interconnect structure 132. Therefore, the routing structure 122, the transistor wafer structures 118, and the interconnect structure 132 may be electrically connected to each other by the via 500. In some embodiments, the material of the via 500 is, for example, copper or tungsten.

In some embodiments, the semiconductor structure 500 may further include a via 502. The via 502 is located between the interconnect structure 132 and the transistor wafer 112 closest to the interconnect structure 132. The via 502 may be electrically connected to the interconnect structure 132 and the transistor wafer 112 closest to the interconnect structure 132. The via 502 may be located in the bonding layer 104 and the bonding layer 116. In some embodiments, the material of the via 502 is, for example, copper or tungsten.

In addition, in the semiconductor structure 20 of FIG. 2 and the semiconductor structure 50 of FIG. 5, the same or similar components are denoted by the same reference symbols, and the description thereof is omitted.

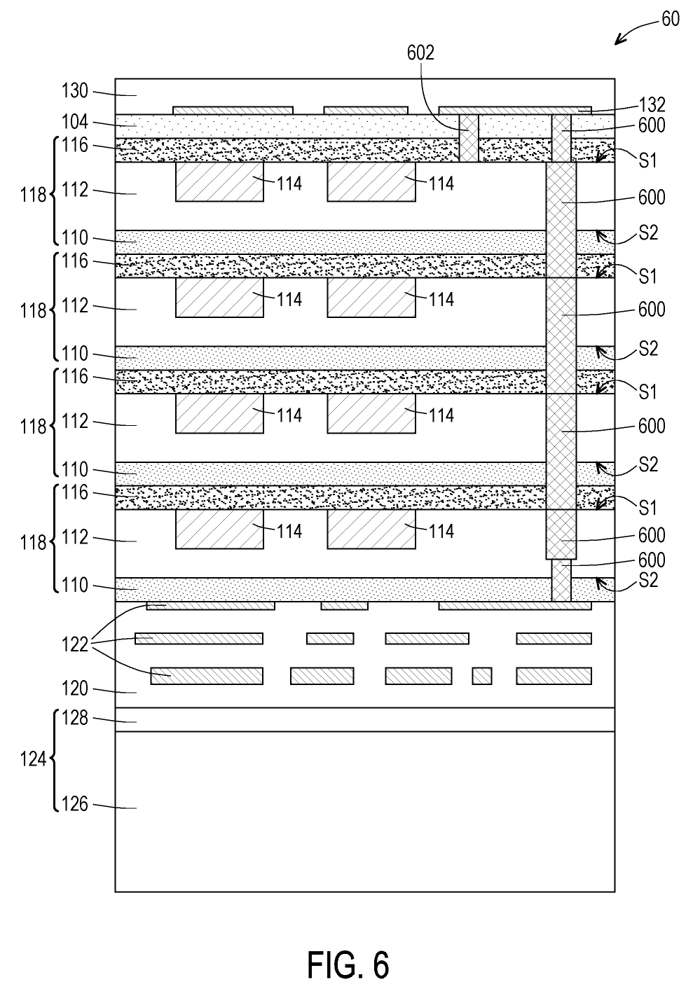

FIG. 6 is a cross-sectional view of a semiconductor structure according to other embodiments of the invention.

Referring to FIGS. 2 and 6, the difference between the semiconductor structure 60 of FIG. 6 and the semiconductor structure 20 of FIG. 2 is as follows. In the semiconductor structure 60, the electrical connection method of the routing structure 122, the transistor wafer structures 118, and the interconnect structure 132 is illustrated as an example. The semiconductor structure 60 may further include vias 600. The vias 600 are located in the transistor wafer structures 118 and are connected to each other. The vias 600 may be electrically connected to the routing structure 122, the transistor wafer structures 118, and the interconnect structure 132. Therefore, the routing structure 122, the transistor wafer structures 118, and the interconnect structure 132 may be electrically connected to each other by the vias 600. The Via 600 may be a single-layer structure or a multilayer structure. In some embodiments, the material of the via 600 is, for example, copper or tungsten.

In some embodiments, the semiconductor structure 600 may further include a via 602. The via 602 is located between the interconnect structure 132 and the transistor wafer 112 closest to the interconnect structure 132. The via 602 may be electrically connected to the interconnect structure 132 and the transistor wafer 112 closest to the interconnect structure 132. The via 602 may be located in the bonding layer 104 and the bonding layer 116. In some embodiments, the material of the via 602 is, for example, copper or tungsten.

In addition, in the semiconductor structure 20 of FIG. 2 and the semiconductor structure 60 of FIG. 6, the same or similar components are denoted by the same reference symbols, and the description thereof is omitted.

In summary, in the semiconductor structure and the manufacturing method thereof in the aforementioned embodiments, the semiconductor structure includes a carrier wafer structure and transistor wafer structures. The transistor wafer structures are stacked on the carrier wafer structure. Each of the transistor wafer structures includes a transistor wafer, a first bonding layer, and a second bonding layer. The transistor wafer has a first side and a second side opposite to each other. The first bonding layer is located on the first side of the transistor wafer. The second bonding layer is located on the second side of the transistor wafer. The first bonding layer of one of two adjacent transistor wafer structures is bonded to the second bonding layer of the other of the two adjacent transistor wafer structures. In this way, each transistor wafer can be manufactured independently, thereby minimizing the thickness of the transistor wafer and reducing the process complexity of the semiconductor structure.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A semiconductor structure, comprising:
a carrier wafer structure; and
transistor wafer structures stacked on the carrier wafer structure, wherein each of the transistor wafer structures comprises:
a transistor wafer having a first side and a second side opposite to each other;
a first bonding layer located on the first side of the transistor wafer; and
a second bonding layer located on the second side of the transistor wafer, wherein
the first bonding layer of one of two adjacent transistor wafer structures is bonded to the second bonding layer of the other of the two adjacent transistor wafer structures.

2. The semiconductor structure according to claim 1, wherein the transistor wafer comprises a transistor.

3. The semiconductor structure according to claim 2, wherein the transistor comprises a planar field-effect-transistor, a fin field-effect-transistor, a gate-all-around field-effect-transistor, or a complementary field-effect-transistor.

4. The semiconductor structure according to claim 2, wherein the transistor comprises an N-type metal oxide semiconductor transistor, a P-type metal oxide semiconductor transistor, or a combination thereof.

5. The semiconductor structure according to claim 1, wherein the carrier wafer structure comprises a carrier wafer and a third bonding layer, and the third bonding layer is located on the carrier wafer.

6. The semiconductor structure according to claim 5, wherein the first bonding layer closest to the carrier wafer structure is bonded to the third bonding layer.

7. The semiconductor structure according to claim 6, further comprising:
a first dielectric layer located on the transistor wafer structure farthest from the carrier wafer structure; and
a routing structure located in the first dielectric layer.

8. The semiconductor structure according to claim 7, further comprising:
a via passing through the transistor wafer structures and electrically connected to the routing structure and the transistor wafer structures.

9. The semiconductor structure according to claim 7, further comprising:
vias located in the transistor wafer structures and connected to each other, wherein the vias are electrically connected to the routing structure and the transistor wafer structures.

10. The semiconductor structure according to claim 5, further comprising:
a first dielectric layer located on the transistor wafer structure closest to the carrier wafer structure; and
a routing structure located in the first dielectric layer.

11. The semiconductor structure according to claim 10, wherein the first dielectric layer is bonded to the third bonding layer.

12. The semiconductor structure according to claim 11, further comprising:
a second dielectric layer located on the transistor wafer structure farthest from the carrier wafer structure; and
an interconnect structure located in the second dielectric layer.

13. The semiconductor structure according to claim 10, further comprising:
a via passing through the transistor wafer structures and electrically connected to the routing structure, the transistor wafer structures, and the interconnect structure.

14. The semiconductor structure according to claim 10, further comprising:
vias located in the transistor wafer structures and connected to each other, wherein the vias are electrically connected to the routing structure, the transistor wafer structures, and the interconnect structure.

15. The semiconductor structure according to claim 1, wherein a thickness of the transistor wafer is less than 300 nanometers.

16. A manufacturing method of a semiconductor structure, comprising:
providing a carrier wafer structure; and
forming transistor wafer structures on the carrier wafer structure, wherein each of the transistor wafer structures comprises:
a transistor wafer having a first side and a second side opposite to each other;
a first bonding layer located on the first side of the transistor wafer; and
a second bonding layer located on the second side of the transistor wafer, wherein
the first bonding layer of one of two adjacent transistor wafer structures is bonded to the second bonding layer of the other of the two adjacent transistor wafer structures.

17. The manufacturing method of the semiconductor structure according to claim 16, wherein the carrier wafer structure comprises a first carrier wafer and a third bonding layer, the third bonding layer is located on the first carrier wafer, and the first bonding layer closest to the first carrier wafer is bonded to the third bonding layer.

18. The manufacturing method of the semiconductor structure according to claim 17, wherein a method of forming each of the transistor wafer structures comprises:
providing second carrier wafer;
forming a release layer on the second carrier wafer;
forming the second bonding layer on the release layer;
forming the transistor wafer on the second bonding layer; and
forming the first bonding layer on the transistor wafer.

19. The manufacturing method of the semiconductor structure according to claim 18, wherein a method of forming the transistor wafer on the second bonding layer comprises bonding the transistor wafer to the second bonding layer.

20. The manufacturing method of the semiconductor structure according to claim 18, further comprising:
after bonding the first bonding layer closest to the carrier wafer structure to the third bonding layer or bonding the first bonding layer of one of the two adjacent transistor wafer structures to the second bonding layer of the other of the two adjacent transistor wafer structures, removing the second carrier wafer from the release layer; and
after removing the second carrier wafer, removing the release layer.
